(19) United States
(12) Patent Application Publication
(10) Pub. No.: US 2004/0079981 A1
(43) Pub. Date: Apr. 29, 2004

(54) Semiconductor device having capacitor

(75) Inventors: Taichi Hirokawa, Hyogo (JP); Akira Matsumura, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/602,051

(22) Filed: Jun. 24, 2003

(30) Foreign Application Priority Data
Oct. 23, 2002 (JP) 2002-308592(P)

(51) Int. Cl. H01L 27/108

(52) U.S. Cl. 257/306

(57) ABSTRACT

A semiconductor device has a capacitor including a storage node as a pair of electrodes isolated from each other by a capacitor dielectric layer and a cell plate, and includes a first contact and interlayer insulation layers formed on the first contact and having holes reaching the first contact. Hole and holes have diameters different from each other, and the diameters discontinuously change on a boundary between hole and holes. Further, the storage node is formed along inner wall surfaces of holes and is electrically connected to the first contact. With this, in the semiconductor device having a capacitor, a capacitor capacity can increase while stably ensuring an electrical connection of a capacitor lower electrode.

### BACKGROUND OF THE INVENTION

1. Field of the Invention

The present invention relates to a semiconductor device having a capacitor and, more specifically, to a semiconductor device having a capacitor including a pair of electrodes which are insulated from each other.

2. Description of the Background Art

High integration of a dynamic random access memory (DRAM) has been accomplished by reducing dimensions of elements. With such high integration and size reduction, however, an SN (Storage Node) is also reduced, which makes it difficult to maintain a capacitor capacity. A malfunction such as a read error or a soft error may occur when the capacity is small. The read error is a misreading due to a decrease in an S/N (Signal to Noise) ratio. The soft error is a phenomenon in which a non-specific 1 bit inverts due to an α ray emitted from a radioisotope.

A memory cell of the DRAM is indicated, for example, in FIG. 1 of Japanese Patent Laying-Open No. 8-288475. Referring to the drawing, a transistor is provided on a semiconductor single crystal substrate, and an interlayer insulator film is stacked so as to cover the semiconductor single crystal substrate and the transistor. A contact hole reaching a diffusion layer of the transistor is formed in the interlayer insulator film. A capacitor lower electrode is electrically conducted to the diffusion layer via the contact hole, and a capacitor insulator film and a cell plate are formed stacked on the capacitor lower electrode. A structure of a memory cell of the DRAM is also disclosed in Japanese Patent Laying-Open No. 9-307080.

In each structure of the memory cells of the DRAM in the above-mentioned two references, however, the diffusion layer of the transistor directly contacts with the capacitor lower electrode. The capacitor lower electrode is formed as thin as possible to make the capacitor capacity as large as possible, as the capacitor lower electrode is formed opposed to a capacitor upper electrode in the contact hole. When the capacitor lower electrode becomes thinner, however, cutting of the capacitor lower electrode (film cutting) or the like may occur on the bottom of the contact hole, which results in an unstable electrical connection of the diffusion layer of the transistor and the capacitor lower electrode.

Therefore, another conductive layer is sometimes formed between the transistor and the capacitor lower electrode to ensure the electrical connection between the transistor and the capacitor lower electrode. In this structure, however, as the contact hole becomes shallower due to the aforementioned another conductive layer, an area of each of the opposed portions of the lower and upper electrodes of the capacitor (referred to as an “opposed area” hereafter) becomes smaller, and the capacitor capacity will be insufficient. This makes it difficult to maintain the capacitor capacity while reducing the size of the elements, and thus a malfunction such as the read error or soft error may occur.

### SUMMARY OF THE INVENTION

An object of the present invention is to provide a semiconductor device having a capacitor which can increase a capacitor capacity while stably ensuring an electrical connection of a capacitor lower electrode (storage node).

A semiconductor device having a capacitor according to the present invention has a capacitor including a pair of electrodes which are insulated from each other, and includes a first conductive layer and an insulation layer formed on the first conductive layer and having a hole reaching the first conductive layer. The hole has a first portion and a second portion having diameters different from each other, and the diameter of the hole discontinuously (abruptly or stepwise) changes at a boundary between the first and second portions. The semiconductor device having a capacitor according to the present invention further includes one electrode of the capacitor formed along an inner wall surface of the hole and electrically connected to the first conductive layer.

In the semiconductor device having a capacitor according to the present invention, a portion of the conductive layer which is conventionally formed below one electrode of the capacitor is removed, and the one electrode of the capacitor is formed also in this portion. Therefore, an opposed area of the one electrode of the capacitor increases by the removed portion of the conductive layer. In addition, electrical connections between the one electrode of the capacitor and other structures are ensured by the first conductive layer. Further, the hole reaching the first conductive layer can be formed so as to have discontinuously changing diameters for first and second portions, because the first and second portions are formed in separate steps. When the diameters of the first and second portions of the hole are made to discontinuously change, a step is formed on a boundary between the first and second portions of the hole. Therefore, the opposed area of the one electrode of the capacitor formed along the inner wall of the hole increases by the amount of the step. In addition, when the one electrode of the capacitor is formed with doped amorphous silicon, the opposed area increases because the one electrode of the capacitor is made to have a rough surface. As a result, the capacitor capacity increases.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are cross-sectional views of schematic structures of a DRAM memory cell of a semiconductor device having a capacitor according to a first embodiment of the present invention.

FIGS. 2-8 are schematic cross-sectional views of successive steps of a manufacturing method of the capacitor of the semiconductor device having a capacitor in the first embodiment of the present invention. FIG. 7A shows a situation in which an embedded layer is completely removed, while FIG. 7B shows a situation in which the embedded layer is partially left.

FIG. 9 is a cross-sectional view of a schematic structure of a DRAM memory cell of a semiconductor device having a capacitor according to a second embodiment of the present invention.

FIGS. 10 and 11 are schematic cross-sectional views of successive steps of a manufacturing method of the capacitor of the semiconductor device having a capacitor in the second embodiment of the present invention.

FIG. 12 is a cross-sectional view of a schematic structure of a DRAM memory cell of a semiconductor device having a capacitor according to a third embodiment of the present invention.

FIGS. 13-15 are schematic cross-sectional views of successive steps of a manufacturing method of the capacitor of the semiconductor device having a capacitor in the third embodiment of the present invention.

### DESCRIPTION OF THE PREFERRED EMBODIMENTS

Embodiments of the present invention are described in the following with reference to the drawings.

### First Embodiment

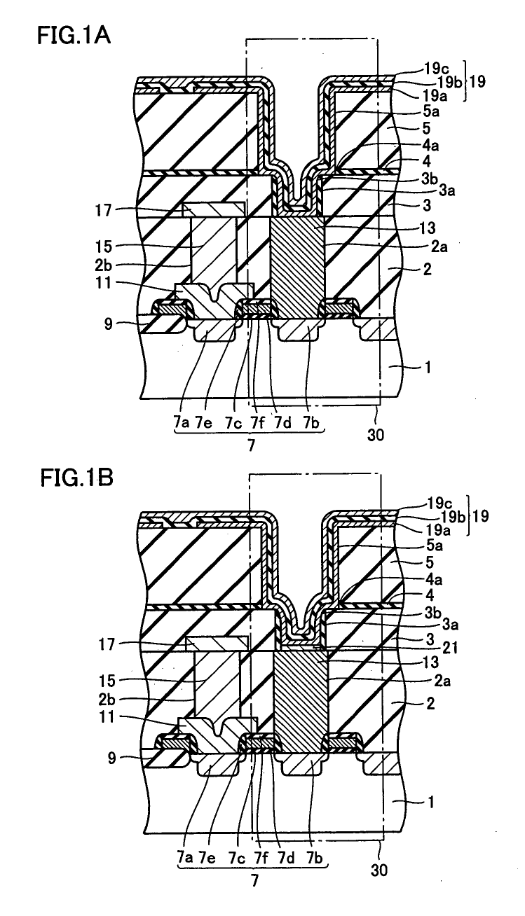

Referring to FIG. 1A, a structure of a DRAM memory cell is shown as an example of a semiconductor device having a capacitor. An MOS (Metal Oxide Semiconductor) transistor 7 is formed on a surface of a silicon substrate 1 electrically separated by a field oxide film 9.

MOS transistor 7 has a pair of source/drain regions 7a, 7b, a gate insulation layer 7c and a gate electrode layer 7d. The pair of source/drain regions 7a, 7b have LDD (Lightly Doped Drain) structures, and are arranged spaced from each other by a prescribed distance. Gate electrode layer 7d is formed on a region between the pair of source/drain regions 7a, 7b with gate insulation layer 7c interposed therebetween. Gate insulation layer 7c is formed, for example, with a silicon oxide film. Gate electrode layer 7d is formed, for example, with a polycrystalline silicon layer doped with an impurity (referred to as a doped polysilicon layer hereafter).

Insulation layers 7e, 7f formed with silicon oxide films, for example, cover around gate electrode layer 7d. A pad layer 11 is formed on one of the pair of source/drain regions 7a. An interlayer insulation layer 2 is formed so as to cover MOS transistor 7 and pad layer 11. Interlayer insulation layer 2 is formed with BPTEOS (Boro Phospho Tetra Ethyl Ortho Silicate) or the like. BPTEOS is a silicon oxide film made of TEOS (Tetra Ethyl Ortho Silicate) and formed so as to include B (boron) and P (phosphorus). In interlayer insulation layer 2, a hole 2a reaching the other of the pair of source/drain regions 7b and a hole 2b reaching pad layer 11 are opened. Conductive layers 13 and 15 are respectively embedded in holes 2a and 2b, each of which conductive layers 13 and 15 is formed with a doped polysilicon layer or the like. A bit line 17 is formed on interlayer insulation layer 2, and bit line 17 is electrically connected to one of the pair of source/drain regions 7a of MOS transistor 7 via conductive layer 15 and pad layer 11.

An interlayer insulation layer 3 formed with BPTEOS or the like, an interlayer insulation layer 4 formed with Si₃N₄ or the like and an interlayer insulation layer 5 formed with BPTEOS or the like are stacked on interlayer insulation layer 2 and bit line 17. A hole reaching conductive layer 13 is formed in these interlayer insulation layers 3-5. The hole has a portion 3a formed in interlayer insulation layer 3, a portion 4a formed in interlayer insulation layer 4 and a portion 5a formed in interlayer insulation layer 5. Portions 4a, 5a of the hole have a diameter different from that of portion 3a. That is, portions 4a, 5a of the hole have a diameter larger than that of portion 3a, and the diameter of the hole discontinuously changes on a boundary between portion 3a and portions 4a, 5a of the hole. A sidewall surface of portion 3a of the hole is covered with an insulation layer 3b formed with Si₃N₄ or the like.

A capacitor 19 includes a storage node 19a (one electrode of the capacitor) and a cell plate 19c (the other electrode of the capacitor), which are a pair of electrodes insulated from each other by a capacitor dielectric layer 19b. Storage node 19a, which is one electrode of capacitor 19, is formed along inner wall surfaces of holes 3a, 4a, 5a and is electrically connected to conductive layer 13. Capacitor dielectric layer 19b and cell plate 19c are stacked on storage node 19a. Storage node 19a is formed, for example, with amorphous silicon doped with an impurity (referred to as doped amorphous silicon hereafter). Capacitor dielectric layer 19b is formed, for example, with Ta₂O₅. Cell plate 19c is formed, for example, with TiN.

A manufacturing method according to this embodiment will now be described.

In this embodiment, the manufacturing method is described only for a region 30 enclosed by broken lines in FIG. 1A.

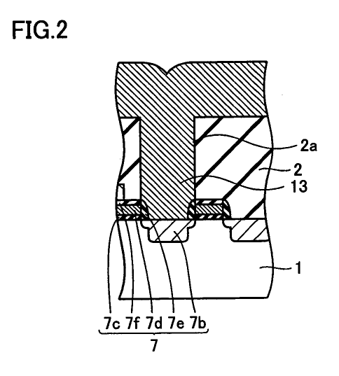

Referring to FIG. 2, MOS transistor 7 is formed on a surface of silicon substrate 1 as follows. Gate insulation layer 7c formed with a silicon oxide film or the like is formed on the surface of silicon substrate 1, and gate electrode layer 7d and insulation layer 7f are formed on this gate insulation layer 7c. Patterning is then performed with common photomechanical technique and etching technique. Silicon substrate 1 is doped with an impurity using gate electrode layer 7d and the like as a mask to form an impurity region 7b of a relatively low concentration.

A sidewall spacer-like insulation layer 7e, which is formed with a silicon oxide film or the like, is formed so as to cover a sidewall of gate electrode layer 7d. Thereafter, silicon substrate 1 is doped with an impurity using gate electrode layer 7d, insulation layer 7e and the like as a mask to form impurity region 7b of a relatively high concentration. With this impurity region of relatively high concentration and the aforementioned impurity region of relatively low concentration, source/drain regions 7a, 7b having LDD structures are formed. MOS transistor 7 is formed with the above-described steps.

Interlayer insulation layer 2, which is formed with BPTEOS or the like, is formed so as to cover MOS transistor 7 formed as such. Hole 2a is then opened in interlayer insulation layer 2 with common photomechanical technique and etching technique, and conductive layer 13 such as doped polysilicon is deposited on interlayer insulation layer 2 to fill the opened hole 2a.

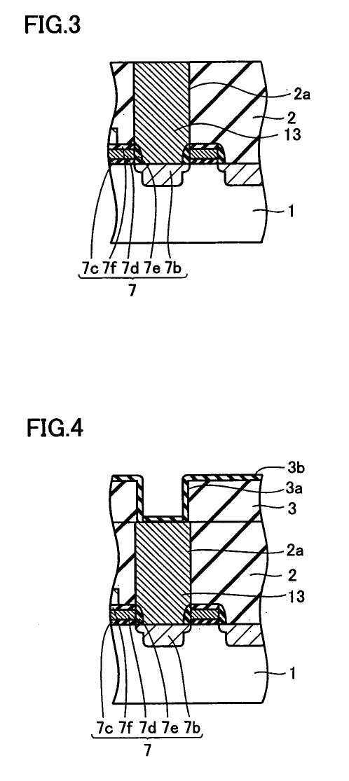

Referring to FIG. 3, conductive layer 13 on interlayer insulation layer 2 is removed by chemical mechanical polishing or etching, and conductive layer 13 is left only within hole 2a.

Referring to FIG. 4, interlayer insulation layer 3, which is formed with BPTEOS or the like, is stacked on interlayer insulation layer 2 and conductive layer 13, and hole 3a reaching conductive layer 13 is formed in interlayer insulation layer 3 with common photomechanical technique and etching technique. With this step, interlayer insulation layer 3 having hole 3a reaching conductive layer 13 is formed on conductive layer 13. Insulation layer 3b, which is formed with Si₃N₄ or the like, is then deposited on bottom and side surfaces of hole 3a and a top surface of interlayer insulation layer 3.

Referring to FIG. 5, anisotropic etching is performed to insulation layer 3b to remove insulation layer 3b on the bottom surface of hole 3a and on interlayer insulation layer 3 to expose top surfaces of interlayer insulation layer 3 and conductive layer 13, and insulation layer 3b is left only on the side surface of hole 3a. A conductive material such as doped polysilicon is then deposited on interlayer insulation layer 3, insulation layer 3b covering the side surface of hole 3a and conductive layer 13, and the conductive material is removed till the top surface of interlayer insulation layer 3 is exposed by chemical mechanical polishing, etching or the like. With this step, an embedded layer 21 filing hole 3a is formed.

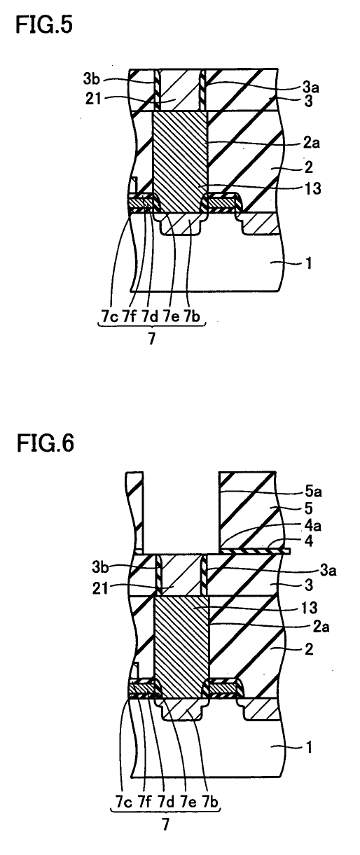

Referring to FIG. 6, interlayer insulation layer 4, which is formed with Si₃N₄ or the like, and interlayer insulation layer 5, which is formed with BPTEOS or the like, are stacked on interlayer insulation layer 3 and embedded layer 21. Holes 4a, 5a connecting to hole 3a and having a diameter larger than that of hole 3a are formed in these interlayer insulation layers 4, 5 with common photomechanical technique and etching technique. With this step, a top surface of embedded layer 21 is exposed.

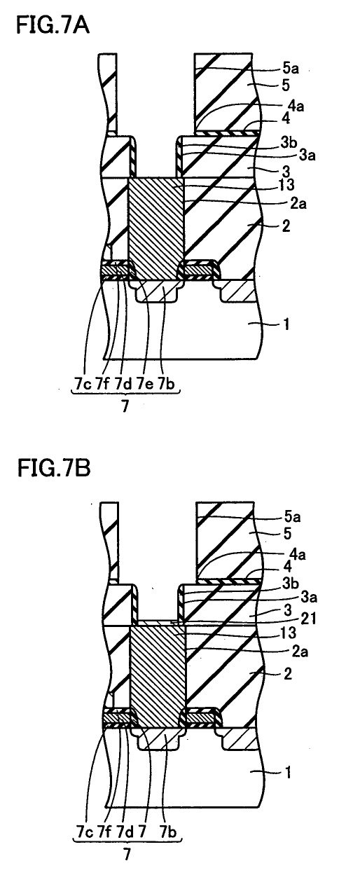

Referring to FIG. 7A, the conductive material of exposed embedded layer 21 is removed by etching or the like. In this embodiment, in which embedded layer 21 is formed with a conductive material, the conductive material of embedded layer 21 need not to be completely removed. FIG. 7B shows a structure in which the conductive material of embedded layer 21 is not completely removed and is partially left.

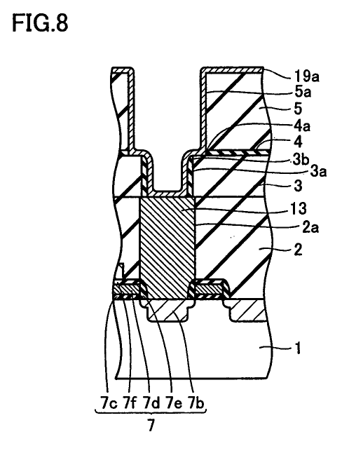

Referring to FIG. 8, a conductive layer 19a for a storage node (one electrode of the capacitor), which is formed with doped amorphous silicon or the like, is deposited along inner wall surfaces of holes 3a, 4a, 5a and top surface of interlayer insulation layer 5. Conductive layer 19a is electrically connected to the other of source/drain 7b of MOS transistor 7 via conductive layer 13. Conductive layer 19a is then patterned with common photomechanical technique and etching technique to form storage node 19a of doped amorphous silicon. As holes 4a and 5a have a diameter larger than that of hole 3a and the diameters of the holes discontinuously change on a boundary between hole 3a and holes 4a, 5a, storage node 19a has a step-like form in the boundary portion. Storage node 19a is made to have a rough surface by depositing doped amorphous silicon and processing to have a rough surface.

Referring to FIG. 1A, capacitor dielectric layer 19b, which is formed with Ta₂O₅ or the like, and cell plate 19c, which is formed with TiN or the like, are then stacked on storage node 19a to form capacitor 19. In the step shown in FIG. 7A, when the conductive material of embedded layer 21 is not completely removed and is partially left as shown in FIG. 7B, the resulting semiconductor device has a structure as shown in FIG. 1B. The semiconductor device having a capacitor is formed with the above-described steps.

In this embodiment, each of interlayer insulation layers 2-5 and capacitor dielectric layer 19b may be formed with an insulator of other materials. In addition, each of conductive layer 13 and embedded layer 21 may be formed with other conductive materials. Further, though doped amorphous silicon is used as one electrode 19a, other conductive materials may be used.

In addition, though holes 4a and 5a have a diameter larger than that of hole 3a in this embodiment, other situations are possible so long as the diameters of holes 4a, 5a and hole 3a are discontinuous.

In the semiconductor device having a capacitor and the manufacturing method thereof according to this embodiment, embedded layer 21 is removed and storage node 19a and cell plate 19c are formed also in this portion. Therefore, the opposed area of the capacitor increases by the amount of the removed embedded layer 21.

In addition, conductive layer 13 is provided between storage node 19a and source/drain region 7b. Therefore, an electrical connection between storage node 19a and source/drain region 7b is stably ensured even if film cutting or the like occurs in storage node 19a.

Further, the hole reaching conductive layer 13 can be formed so as to have first and second portions having discontinuously changing diameters, because portion 3a and portions 4a, 5a of the hole are formed in separate steps. When the diameters of portion 3a and portions 4a, 5a of the hole are discontinuously changed, a step is formed on a boundary between portion 3a and portions 4a, 5a of the hole. A step is also formed on storage node 19a formed along the inner wall of the hole, and therefore the opposed area of storage node 19a and cell plate 19c increases by the amount of the step. In addition, when storage node 19a is formed with doped amorphous silicon, the opposed area increases because storage node 19a is made to have a rough surface by depositing doped amorphous silicon and processing to have a rough surface. As a result, the capacitor capacity increases.

In the semiconductor device having a capacitor in this embodiment, the insulation layer, in which holes 3a, 4a, 5a are formed, may be formed with a single interlayer insulation layer, or may be formed, for example, with three interlayer insulation layers 3-5 as shown in FIG. 1 or the like. When the insulation layer with holes 3a, 4a, 5a formed therein is formed with interlayer insulation layers 3-5, it is preferable to form portion 3a of the hole having a smaller diameter in interlayer insulation layer 3, and to form portions 4a, 5a having a larger diameter in interlayer insulation layers 4, 5.

With this, a step can easily be made on a boundary between portion 3a and portions 4a, 5a of the hole. Therefore, the capacitor capacity easily increases. Herein, interlayer insulation layers 4, 5 with portions 4a, 5a of the hole formed therein may be formed with a single interlayer insulation layer, which layer is different from interlayer insulation layer 3 with portion 3a of the hole formed therein.

In addition, as an opening of an upper portion of the hole becomes larger by making the diameter of portions 4a, 5a of the hole larger than that of portion 3a, an aspect ratio increases, which results in good coverage during the formation of storage node 19a of the capacitor.

Further, in the manufacturing method of the semiconductor device having a capacitor in this embodiment, the embedded layer is preferably formed with a conductive material. This enables the embedded layer to be formed concurrently with other conductive layers such as a plug layer, which can suppress increase in manufacturing steps.

It is preferable that, the semiconductor device having a capacitor in this embodiment further includes embedded layer 21 located between conductive layer 13 and storage node 19a and electrically connected to both of conductive layer 13 and storage node 19a.

With this, the electrical connection between conductive layer 13 and storage node 19a will not be affected even when embedded layer 21 is not completely removed as shown in FIG. 7B in the step of removing embedded layer 21, because storage node 19a formed in the following step and the left portion of embedded layer 21 are electrically connected as shown in FIG. 1B. Therefore, the control of etching of embedded layer 21 becomes easier.

### Second Embodiment

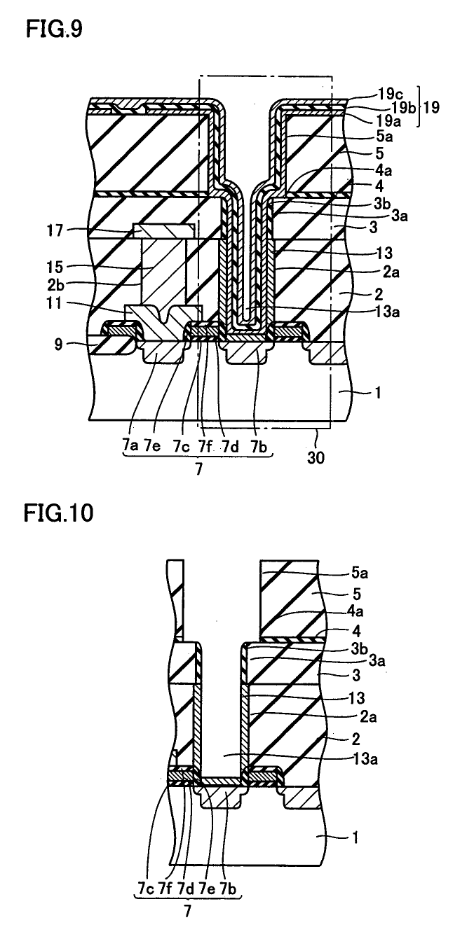

Referring to FIG. 9, a structure according to this embodiment is different from that in the first embodiment in the following points. That is, conductive layer 13 has a concave portion 13a connecting to holes 3a, 4a, 5a, and storage node 19a is formed along an inner wall surface of concave portion 13a and is opposed to cell plate 19c within concave portion 13a.

As other structures are substantially the same as those in the first embodiment described above, the same members are indicated by the same characters and the descriptions thereof will not be repeated.

A manufacturing method according to this embodiment will now be described.

In this embodiment, the manufacturing method is described only for region 30 enclosed by broken lines in FIG. 9.

In the manufacturing method of this embodiment, the steps similar to those in the first embodiment which are shown in FIGS. 2-6 are first performed. Thus, the descriptions thereof will not be repeated herein.

Thereafter, referring to FIG. 6, embedded layer 21 formed with a conductive material and conductive layer 13 are removed by etching. With this step, concave portion 13a connecting to holes 3a, 4a, 5a is formed in conductive layer 13, as shown in FIG. 10. The most notable point in this embodiment is that, conductive layer 13 is also removed in addition to embedded layer 21.

If embedded layer 21 and conductive layer 13 are formed with the same conductive material such as doped polysilicon, conductive layer 13 can be etched along with embedded layer 21 by making an etching time longer than that in the first embodiment. When the etching time is too long, on the other hand, a lower portion of conductive layer 13 will not be left, and the other of source/drain 7b of MOS transistor 7 will be exposed. This is not preferable because the electric connection between storage node 19a and the other of source/drain 7b of MOS transistor 7 is not ensured if storage node 19a (FIG. 9) formed thereon is broken. Therefore, the etching time is selected so as to etch conductive layer 13 and not to expose the other of source/drain 7b of MOS transistor 7. Thus, conductive layer 13 has concave portion 13a connecting to holes 3a, 4a, 5a.

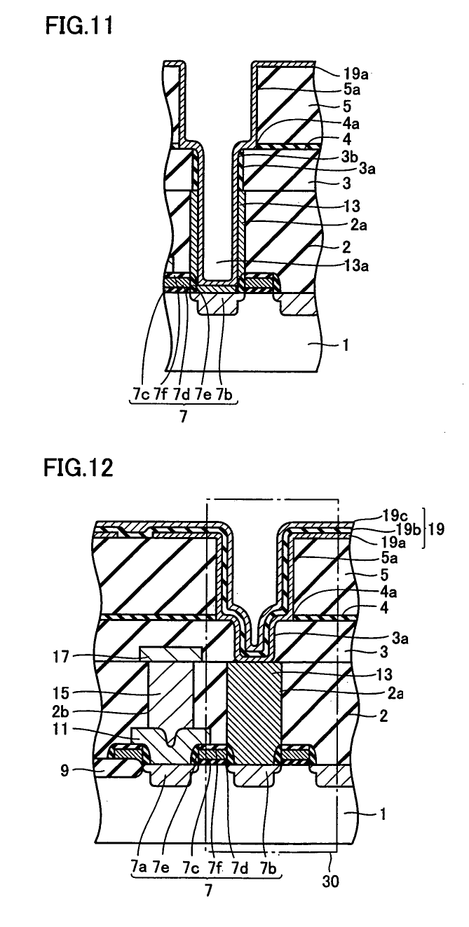

Referring to FIG. 11, storage node 19a, which is formed with doped amorphous silicon or the like, is deposited along the inner walls of holes 3a, 4a, 5a, the inner wall of concave portion 13a of conductive layer 13 and the top surface of interlayer insulation layer 5. With this, storage node 19a is electrically connected to the other of source/drain 7b of MOS transistor 7 via the bottom portion of conductive layer 13.

As holes 4a and 5a have a diameter larger than that of hole 3a and the diameters of the holes discontinuously change on a boundary between hole 3a and holes 4a, 5a, storage node 19a has a step-like form in an upper portion of hole 3a. In addition, storage node 19a is made to have a rough surface by depositing doped amorphous silicon and processing to have a rough surface after doped amorphous silicon is deposited as storage node 19a.

Referring to FIG. 9, capacitor dielectric layer 19b, which is formed with Ta₂O₅ or the like, and cell plate 19c, which is formed with TiN or the like, are stacked on storage node 19a to form capacitor 19. The semiconductor device having a capacitor is formed with the above-described steps.

In this embodiment, interlayer insulation layers 2-5 and capacitor dielectric layer 19b may be formed with insulators of other materials. In addition, each of conductive layer 13 and embedded layer 21 may be formed with other conductive materials. Further, though doped amorphous silicon is used as one electrode 19a, other conductive materials may be used.

In addition, though holes 4a and 5a have a diameter larger than that of hole 3a in this embodiment, other situations are possible so long as the diameters of holes 4a, 5a and hole 3a are discontinuous.

In addition to the effects obtained with the first embodiment, the semiconductor device having a capacitor in this embodiment further has effects as follows.

Concave portion 13a is formed in conductive layer 13, and storage node 19a and cell plate 19c are opposed to each other also in this concave portion 13a. Therefore, the opposed area of the capacitor further increases by the amount of concave portion 13a, and thus the capacitor capacity increases. On the other hand, as conductive layer 13 is left in the bottom portion of concave portion 13a, the electrical connection between storage node 19a and source/drain region 7b can stably be ensured.

### Third Embodiment

Though the sidewall of portion 3a of the hole is covered with insulation layer 3b as shown in FIG. 1 in the first embodiment, such an insulation layer 3b is not provided in this embodiment, as shown in FIG. 12.

As other structures are substantially the same as those in the first embodiment described above, the same members are indicated by the same characters and the descriptions thereof will not be repeated.

A manufacturing method according to this embodiment will now be described.

In this embodiment, the manufacturing method is described only for region 30 enclosed by broken lines in FIG. 12.

In the manufacturing method of this embodiment, the steps similar to those in the first embodiment which are shown in FIGS. 2 and 3 are first performed. Thus, the descriptions thereof will not be repeated herein.

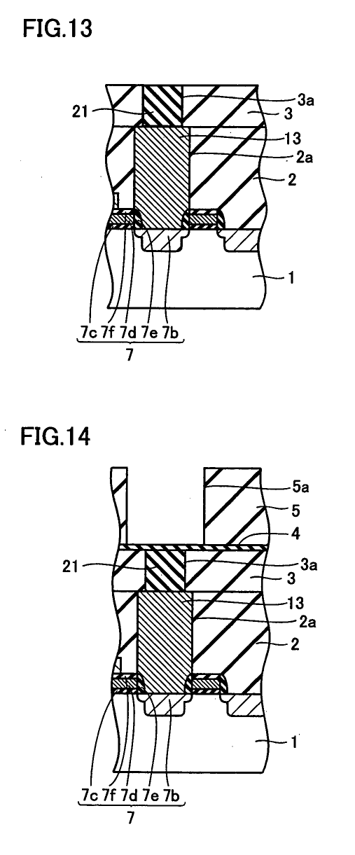

Thereafter, referring to FIG. 13, interlayer insulation layer 3 formed with BPTEOS or the like is stacked on interlayer insulation layer 2 and conductive layer 13, and hole 3a reaching conductive layer 13 is formed with common photomechanical technique and etching technique. With this step, interlayer insulation layer 3 having hole 3a reaching conductive layer 13 is formed. An especially notable point in this embodiment is that, an insulator formed with Si₃N₄ or the like is deposited on interlayer insulation layer 3 and conductive layer 13 so as to fill hole 3a. The insulator on interlayer insulation layer 3 is then removed with chemical mechanical polishing, etching or the like. With this step, embedded layer 21 filling hole 3a is formed.

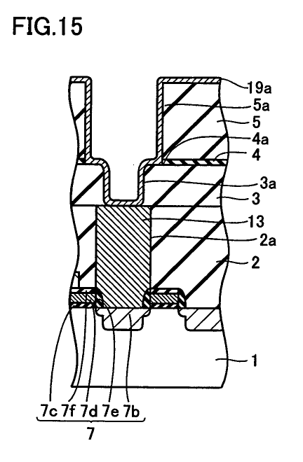

Referring to FIG. 14, interlayer insulation layer 4 formed with Si₃N₄ or the like and interlayer insulation layer 5 formed with BPTEOS or the like are stacked on interlayer insulation layer 3 and embedded layer 21, and hole 5a is then formed with common photomechanical technique and etching technique to expose interlayer insulation layer 4.

Referring to FIG. 15, hole 4a is opened with common photomechanical technique and etching technique in a portion of interlayer insulation layer 4 which is exposed by hole 5a, and an insulator of embedded layer 21 filling hole 3a is removed with etching or the like. In this embodiment, the opening of hole 4a and removing of embedded layer 21 are performed in one removing step, because interlayer insulation layer 4 and embedded layer 21 are both formed with insulators.

Thereafter, storage node 19a, which is formed with doped amorphous silicon or the like, is deposited along the inner wall surfaces of holes 3a, 4a, 5a and the top surface of interlayer insulation layer 5. With this, storage node 19a is electrically connected to the other of source/drain 7b of MOS transistor 7 via conductive layer 13.

As holes 4a and 5a have a diameter larger than that of hole 3a and the diameters of the holes discontinuously change on a boundary between hole 3a and holes 4a, 5a, storage node 19a has a step-like form in an upper portion of hole 3a. In addition, storage node 19a is made to have a rough surface by depositing doped amorphous silicon and processing to have a rough surface after doped amorphous silicon is deposited as storage node 19a.

Referring to FIG. 12, capacitor dielectric layer 19b, which is formed with Ta₂O₅ or the like, and cell plate 19c, which is formed with TiN or the like, are stacked on storage node 19a to form capacitor 19. The semiconductor device having a capacitor is formed with the above-described steps.

In this embodiment, embedded layer 21, interlayer insulation layers 2-5 and capacitor dielectric layer 19b may be formed with insulators of other materials. In addition, conductive layer 13 may be formed with other conductive materials. Further, though doped amorphous silicon is used as one electrode 19a, other conductive materials may be used.

In addition, though holes 4a and 5a have a diameter larger than that of hole 3a in this embodiment, other situations are possible so long as the diameters of holes 4a, 5a and hole 3a are discontinuous.

In the manufacturing method of the semiconductor device having a capacitor according to the present invention, the embedded layer is formed with an insulation layer. With this, as a second insulation layer (interlayer insulation layer 4) and the embedded layer filling a first hole (hole 3a) are both formed with insulators, the formation of the second insulation layer having a second hole (hole 4a) and removing of the embedded layer are performed in one removing step.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a capacitor including a pair of electrodes insulated from each other, comprising:
a first conductive layer;
an insulation layer formed on said first conductive layer and having a hole reaching said first conductive layer, wherein
said hole has a first portion and a second portion having diameters different from each other, the diameter of said hole discontinuously changes at a boundary between said first portion and said second portion; and
one electrode of said capacitor formed along an inner wall surface of said hole and electrically connected to said first conductive layer.

2. The semiconductor device having a capacitor according to claim 1, wherein
said insulation layer has a first insulation layer and a second insulation layer formed on said first insulation layer,
said first portion of said hole is formed in said first insulation layer, and
said second portion of said hole is formed in said second insulation layer and has a diameter larger than a diameter of said first portion.

3. The semiconductor device having a capacitor according to claim 1, further comprising
a second conductive layer located between said first conductive layer and said one electrode and electrically connected to both of said first conductive layer and said one electrode.

4. The semiconductor device having a capacitor according to claim 1, wherein
said first conductive layer has a concave portion connecting to said hole, and said one electrode is formed along an inner wall surface of said concave portion.
